(19) United States
(12) Patent Application Publication
(10) Pub. No.: US 2025/0280499 A1
(43) Pub. Date: Sep. 4, 2025

(54) METHODS AND APPARATUS TO CONNECT A SEMICONDUCTOR PACKAGE TO A CIRCUIT BOARD

(71) Applicant: Intel Corporation, Santa Clara, CA (US)

(72) Inventors: Saikat Mondal, Chandler, AZ (US); Dhanya Athreya, Chandler, AZ (US); Steven Adam Klein, Chandler, AZ (US); Zhichao Zhang, Chandler, AZ (US)

(21) Appl. No.: 18/592,321

(22) Filed: Feb. 29, 2024

(51) Int. Cl. H05K 1/18; H01L 23/00; H01L 23/13; H01L 23/14; H01L 25/065; H01L 25/16; H05K 1/03

(52) U.S. Cl. CPC H05K 1/181; H01L 23/13; H01L 23/145; H01L 24/05; H01L 24/06; H01L 24/16; H01L 25/0655; H01L 25/167; H05K 1/0366; H01L 2224/05553; H01L 2224/05555; H01L 2224/0603; H01L 2224/06051; H01L 2224/06132; H01L 2224/06133; H01L 2224/06177; H01L 2224/16225; H01L 2924/1431; H01L 2924/1432; H01L 2924/1433; H01L 2924/14335; H05K 2201/09227; H05K 2201/10121; H05K 2201/10189; H05K 2201/10325; H05K 2201/10378; H05K 2201/10522; H05K 2201/10719; H05K 2201/10734

(57) ABSTRACT

Systems, apparatus, articles of manufacture, and methods to connect a semiconductor package to a circuit board are disclosed. An example apparatus includes an interposer having a first side and a second side opposite the first side. A semiconductor package couples to the first side of the interposer via first contacts on a first surface of the semiconductor package. The semiconductor package includes second contacts on the first surface of the semiconductor package. The second contacts spaced apart from the first contacts. The second contacts to electrically couple to third contacts in a socket dimensioned to receive the interposer and the semiconductor package.

### FIELD OF THE DISCLOSURE

This disclosure relates generally to semiconductor packages and, more particularly, to methods and apparatus to connect a semiconductor package to a circuit board.

### BACKGROUND

In recent years, the variety of electronic devices which incorporate semiconductor or integrated circuit (IC) packages have grown considerably. Some such electronic devices include cellular phones, portable computers, hand-held devices, etc. These electronic devices typically include a circuit board on which a number of semiconductor packages are secured to provide multiple electronic functions. Different approaches to connecting integrated circuits to underlying circuit boards includes using monolithic packages and using package-on-interposer (PoINT) technology.

### BRIEF DESCRIPTION OF THE DRAWINGS

FIG. 1 is a cross-sectional view of an example integrated circuit (IC) device assembly including an example package-on-interposer (PoINT) device inserted into an example socket on a circuit board in accordance with teachings disclosed herein.

FIG. 2 is a cross-sectional view of the example IC device assembly of FIG. 1 with the example PoINT device spaced apart from example socket.

FIG. 3 is an exploded view of the example IC device assembly of FIG. 1.

FIG. 4 is a bottom view of an example semiconductor package of the example PoINT device of FIGS. 1-3.

FIG. 5 is a cross-sectional view of another example IC device assembly in accordance with teachings disclosed herein.

FIG. 6 is a cross-sectional view of another example IC device assembly in accordance with teachings disclosed herein.

FIG. 7 is a flowchart representative of an example method to manufacture any one of the example IC device assemblies of FIGS. 1-6.

FIG. 8 is a top view of a wafer including dies that may be included in an IC package constructed in accordance with teachings disclosed herein.

FIG. 9 is a cross-sectional side view of an IC device that may be included in an IC package constructed in accordance with teachings disclosed herein.

FIG. 10 is a cross-sectional side view of an IC package constructed in accordance with teachings disclosed herein.

FIG. 11 is a cross-sectional side view of an IC device assembly that may include an IC package constructed in accordance with teachings disclosed herein.

FIG. 12 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

Package-on-Interposer (PoINT) technology is a cost-effective solution helping to realize smaller packages relative to monolithic packages. As a result, PoINT technology can significantly lower package costs relative to monolithic packages. However, the performance of PoINT devices degrades compared to monolithic packages because there are more physical transition layers. Specifically, PoINT devices include one or more semiconductor dies and/or packages (sometimes also referred to as patches) mounted onto an interposer that may be used to interconnect the dies and/or packages with a circuit board (e.g., through a socket constructed to receive the interposer). Thus, circuit assemblies using PoINT devices include an additional interconnect transition between the dies and/or packages and the interposer that is not present in monolithic packages. This additional transition results in more impedance discontinuity with more opportunity for signal reflection. Such impedance discontinuities are particularly problematic as data rates increase.

In known PoINT architectures, the interposer serves to pass through signals between a processor die or package mounted on the interposer and other components (e.g., memory, peripheral component interconnect express (PCIe) connections, etc.) mounted on a circuit board with the signals also passing through a socket and the circuit board. Some example PoINT devices disclosed herein include at least some of the other components (e.g., memory, PCIe connections, etc.) with which the processor package is to communicate mounted directly onto the interposer with the processor package. In this manner, the processor package can communicate with these other components without the discontinuities defined by the transitions between the interposer and the socket, and between the socket and the circuit board. The processor package of some example PoINT devices disclosed herein also includes interconnects that bypass the interposer to directly connect with an underlying socket on a circuit board to communicate with other components via the circuit board. Bypassing the interposer in this manner eliminates the extra discontinuity that would otherwise result if an interposer was communicatively coupled between the processor package on the PoINT device and the socket on the circuit board. As a result, examples disclosed herein enable high speed connectivity by reducing discontinuities both by (1) positioning components directly on the interposer so that signals do not need to pass through a socket and circuit board, and (2) bypassing the interposer for signals that are to pass through the socket to the circuit board. Not only does this approach reduce discontinuities, it positions some of the other components (e.g., memory, PCIe connectors) closer to the processor package of the PoINT device (e.g., directly on the interposer) for improved performance.

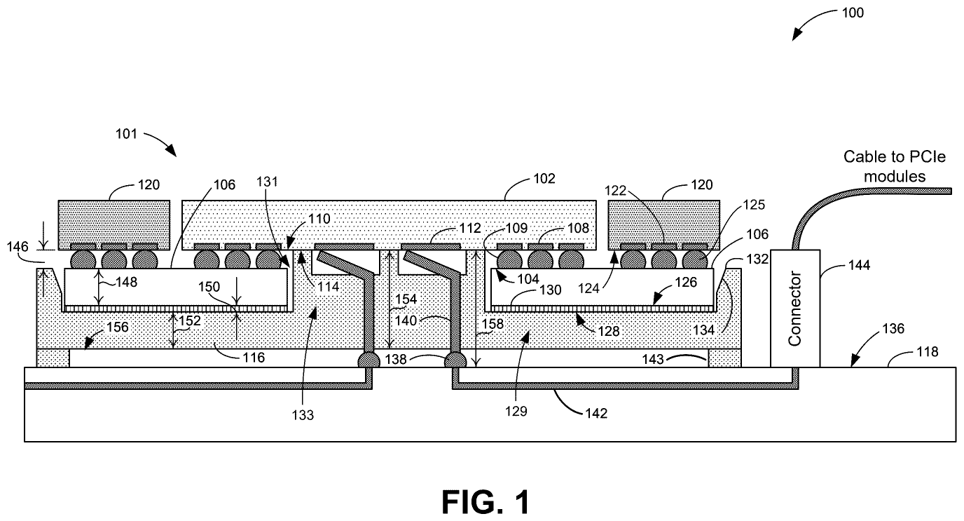

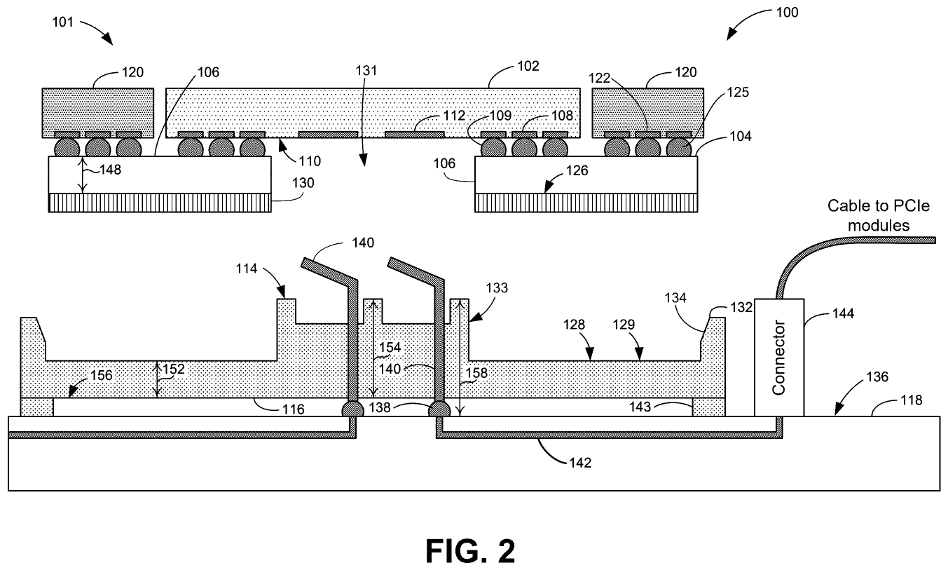

FIG. 1 is a cross-sectional view of an example IC device assembly 100 constructed in accordance with teachings disclosed herein with an example package-on-interposer (PoINT) device 101 inserted into an example socket 116 on a circuit board 118 (e.g., a motherboard or other printed circuit board (PCB)). FIG. 2 is a cross-sectional view of the example IC device assembly 100 of FIG. 1 with the example PoINT device 101 spaced apart from the example socket 116. In the illustrated example, the PoINT device 101 includes an integrated circuit (ICs) or semiconductor die or package 102 (e.g., a first semiconductor package), such as a processor or central processing unit (CPU package) that is coupled to a first side 104 of an interposer 106 via an array of contact pads or lands 108 (e.g., first contacts) on a mounting surface 110 (e.g., a bottom surface) of the semiconductor package 102. In some examples, the semiconductor package 102 may include balls, pins, and/or pads, in addition to or instead of the contact pads 108, to enable the electrical coupling of the semiconductor package 102 to the first side 104 of the interposer 106. In some examples, the semiconductor package 102 includes a package substrate that provides mechanical support for a semiconductor die of the package 102 supported thereon. In some such examples, the package substrate provides an electrical interface between the semiconductor die mounted thereon and external components (e.g., the interposer 106 and the socket 116). In some examples, the semiconductor package 102 does not include a package substrate. That is, in some examples, the semiconductor package 102 is simply a semiconductor die that is directly mounted on to the interposer 106. In such examples, the interposer 106 serves the function of a package substrate. Thus, both interposers and package substrates are collectively referred to as substrates herein. Although similar in function, in some instances, the construction of the interposer 106 may differ from known package substrate technologies. For instance, unlike a package substrate, the interposer 106 of the illustrated example often has a more sophisticated structure, featuring a denser array of interconnects, vias, and through-silicon vias (TSVs) to facilitate high-bandwidth communication between the integrated components. Interposers enable dense integration of multiple components within a small footprint, allowing for more efficient use of space and improved system-level integration.

A package substrate generally includes a package core (that provides mechanical stability) and a build-up region on one or both sides of the core. The package core may be composed of purely organic or purely glass-based material. The build-up region(s) of a package substrate include layers of organic insulating material (e.g., laminated layers of prepreg) with intervening metal layers to define conductive traces and/or other metal features (e.g., ground planes) facilitating signal routing and power distribution.

An interposer can have a core layer (that provides mechanical stability) and insulating layers built on top and bottom of the core layer (e.g., in build-up regions) between layers of metal defining conductive traces and other metal features for signal routing and power distribution. Unlike the package core of a package substrate, which can be purely organic, or glass based and does not contain glass fiber weave, the interposer 106 of the illustrated example is constructed more like a printed circuit board. That is, in some examples, the core layer of an interposer can be composed of an organic material of epoxy resin material that is reinforced with woven glass fiber (e.g., flame retardant 4 (FR-4)). The core layer provides structural support and stability to the interposer. It serves as the main substrate. The FR-4 material offers electrical insulation, mechanical strength, and dimensional stability. The weave pattern of the glass fiber helps distribute mechanical stresses evenly across the interposer, reducing the risk of cracking or delamination. It also enhances thermal conductivity, aiding in heat dissipation. The woven glass fiber enhances the material's tensile strength and prevents warping. In some examples, the insulating material of the build-up regions(s) of the interposer 106 is an organic material (e.g., laminated layers of prepreg). Additionally or alternatively, in some examples, the build-up regions(s) of the interposer 106 may employ an epoxy resin with woven glass fiber (e.g., FR-4) similar to the core layer as the insulating material. The epoxy resin (in the core layer and/or the insulating layers) acts as a binder that holds the glass fiber weave together, forming a strong and durable composite material. Epoxy resin offers excellent adhesion to the glass fiber, ensuring a robust bond. The epoxy resin also provides electrical insulation properties and resistance to environmental factors such as moisture and chemicals.

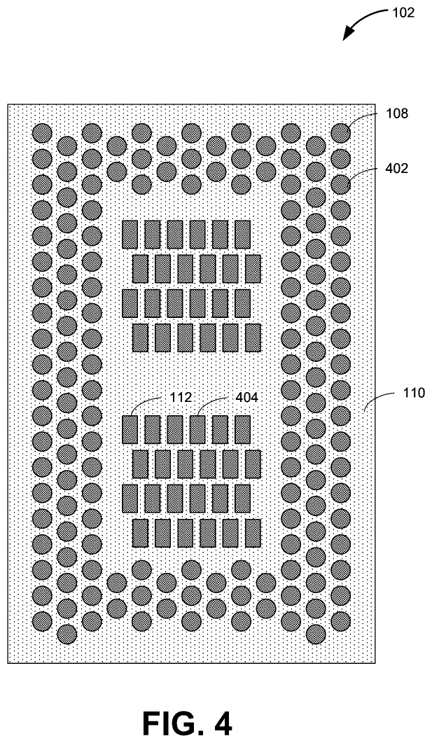

The array of contact pads or lands 108 (e.g., ball grid array (BGA) pads) electrically couples to the interposer 106 via a ball grid array 109. The ball grid array 109 is a mid-level interconnect between the semiconductor package 102 and the interposer 106. In other examples, the interposer 106 includes an array of contact pads and the semiconductor package includes the interfacing ball grid array 109. The array of contact pads 108 has a first shape 402, as described below in connection with FIG. 4. In this example, the semiconductor package 102 includes second contacts 112 on the mounting surface 110 of the semiconductor package 102. The second contacts 112 are spaced apart from the first contacts (e.g., array of contact pads or lands 108). The second contacts 112 enable the electrical coupling of the semiconductor package 102 to pins 140 (e.g., contacts) on the socket 116 that is mounted on top of the circuit board 118. More particularly, in some examples, the second contacts 112 maybe a land grid array (LGA) pads that are urged against respective ones of the pins 140 when the PoINT device 101 is inserted into the socket 116 and engages (or at least comes into close contact with) a contact surface 114 (e.g., a seating plane) of the socket 116. Thus, in this example, the second contacts 112 electrically coupled to the pins 140 define interconnects that bypass the interposer 106 to directly connect the semiconductor package 102 with the circuit board 118 through the underlying socket 116 to communicate with other components via the circuit board 118. In some examples, the other components include an external component (e.g., PCIe connector 144). The second contacts 112 have a second shape 404 that is different from the first shape 402 of the first contacts 108, as described below in connection with FIG. 4. As shown in FIG. 2, when the PoINT device 101 is removed from the socket 116, the pins 140 extend above the contact surface 114.

As shown in the illustrated example, additional semiconductor dies or packages 120, such as a memory (e.g., double data rate (DDR)) packages are also coupled to the first side 104 of the interposer 106 via arrays of contact pads or lands 122 on a mounting surface 124 (e.g., a bottom surface) of the additional (second) semiconductor packages 120. The arrays of contact pads or lands 122 on the additional semiconductor packages 120 electrically couple to the interposer 106 via associated ball grid arrays 125 on the interposer. In other examples, the interposer 106 includes arrays of contact pads and the additional semiconductor package 120 includes interfacing ball grid arrays. In some examples, the additional semiconductor packages 120 may include balls, pins, and/or pads, in addition to or instead of the contact pads 122, to enable the electrical coupling of the additional packages 120 to the first side 104 of the interposer 106. In this example, the interposer 106 includes internal routing to electrically couple the first semiconductor package 102 to the additional semiconductor packages 120. That is, individual balls in the first ball grid array 109 (connected to the first semiconductor package 102) are electrically coupled through the interposer 106 to corresponding balls in the second ball grid arrays 125 (connected to the additional semiconductor packages 120). The second ball grid arrays 125 are mid-level interconnects between the additional (second) semiconductor packages 120 and the interposer 106. The first semiconductor package 102 is electrically coupled to the second semiconductor package 120 via the mid-level interconnect on the interposer 106, and independent of the socket 116. The first semiconductor package 102 (e.g., processor package) can communicate with the second semiconductor packages 120 (e.g., memory packages) without the discontinuities defined by the transitions between the interposer 106 and the socket 116, and between the socket 116 and the circuit board 118.

As noted above, in some examples, the interposer 106 is a substrate that includes glass, or organic materials (e.g., a core layer composed of an epoxy resin reinforced by woven fiberglass) and incorporates metal layers for electrical connections and signal routing. In some examples, the signal routing is to provide electrical interconnections between the separate semiconductor dies or semiconductor packages 102, 120. In some examples, the interposer 106 incorporates through-silicon vias (TSVs) for vertical connections between different layers. In some examples, the TSVs extend to and electrically connect with interconnects or contacts (e.g., pins) on and/or within the socket 116. However, in other examples (such as the example shown in FIG. 1), there is no direct electrical connection between the interposer 106 and the socket 116. Thus, in some examples, TSVs may be omitted from the interposer 106.

As shown in the illustrated example, the first side 104 of the interposer 106 is connected to the first contacts 108 of the first semiconductor package 102 and the contact pads 122 of the additional semiconductor packages 120. The second side 126 of the interposer 106 is physically coupled to a contact surface 128 a first portion 129 of the socket 116. However, in this example, the interposer 106 is devoid of electrical connections with the underlying socket 116. In other examples, the second side 104 of the interposer 106 includes one or more contacts that electrical couple with the interposer 106 (e.g., with contacts similar to the pins 140 electrically couplable with the contacts 112 of the semiconductor package 102. In some examples, the interposer 106 is to be between the first contacts 108 of the first semiconductor package 102 and the contact surface 128 of the socket 116. Additionally, the interposer 106 is to be between the contact pads 122 of the second semiconductor packages 120 and the contact surface 128 of the socket 116. In this example, the contact surface 128 is recessed relative to the contact surface 114 that is to engage the mounting surface 110 of the first semiconductor package 102. In some examples, the socket 118 can be a zero-insertion-force (ZIF) socket, a land grid array (LGA) socket or any other type of socket depending on the specific requirements of the system. In some examples, the socket 118 includes a chamfer 132 to facilitate the alignment of the interposer 106 within the socket 118. The interposer 106 may be connected to the socket 116 on the circuit board 118 utilizing solder, an adhesive, a compression (e.g., spring loaded) connectors, etc.

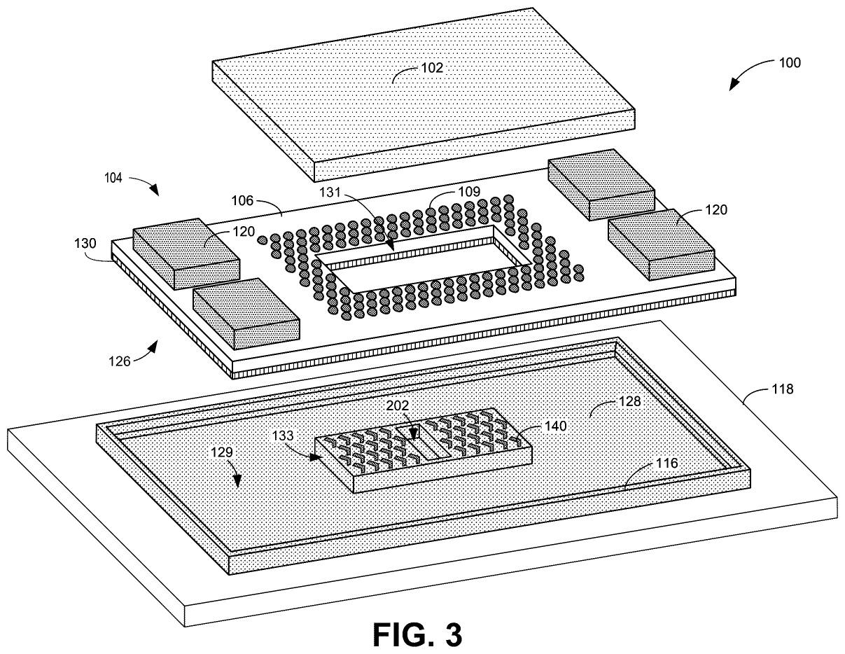

In the illustrated example of FIGS. 1 and 2, the interposer 106 appears to be in two parts. However, in some examples, these parts are different portions of a single interposer connected at locations not shown in the cross-sectional view of FIGS. 1 and 2 but shown in the illustrated example of FIG. 3 discussed further below. More particularly, in some examples, the interposer 106 includes an opening or cutout 131 aligned with the second contacts 112 of the first semiconductor package 102 so that the interposer 106 is spaced apart from the second contacts 112 of the first semiconductor package 102. In some examples, the second contacts 112 of the first semiconductor package 102 extend across (e.g., the contacts 112 face towards and/or face into) the opening or cutout 131 of the interposer 106. Thus, as shown most clearly in FIG. 2, the second contacts 112 are exposed through the opening 131 of the interposer 106.

As shown in the illustrated example, a second portion 133 of the socket 116 is to extend into (e.g., through) the cutout 131 towards the first semiconductor package 102. The second portion 133 of the socket 116 that extends through the cutout 131 in the interposer 106 includes the pins 140. As shown in the illustrated example of FIG. 1, when the PoINT device 101 is plugged or inserted into the socket 116, the pins 140 electrically couple to the second contacts 112 of the first semiconductor package 102 exposed through the opening 131 of the interposer 106. In this example, the interposer 106 is not between the second contacts 112 on the first semiconductor package 102 and the socket 116. Whereas the second portion 133 of the socket 116 is constructed to fit through the cutout 131 of the interposer 130, in some examples, the first portion 135 is to interface with (e.g., align with) the interposer 130. More particularly, as noted above, the first portion 129 of the socket 116 includes and/or defines the contact surface 128. In some examples, as shown most clearly in FIG. 3, the first portion 129 surrounds the second portion 133.

In some examples, the chamfer 132 on the socket 116 has a beveled or angled edge or surface 134. The chamfer 132 aids in the alignment of the interposer 106 with the socket 116. When the interposer 106 is inserted into the socket 116, the chamfered edges 134 guide the interposer 106 into the correct position. In the illustrated example, although the interposer 106 is inserted into the socket 116, the interposer 106 is not electrically coupled with the socket 116. However, the interposer 106 still needs to be aligned with the socket 116 so that the second contacts 112 on the first semiconductor package 102 (attached to the interposer 106) are aligned with corresponding pins 140 of the socket 106. Inasmuch as the pins 140 extend through the cutout 131 of the interposer 106, the first semiconductor package 102 is able to electrically couple with the socket 116 independent of the interposer 106.

The socket 116 is coupled to a first face 136 of the circuit board 118 by coupling components 138 (e.g., electrical contacts or interconnects). The coupling components 138 may electrically and mechanically couple the socket 116 to the circuit board 118, and may include solder balls (as shown in FIG. 1), and/or any other suitable electrical and/or mechanical coupling structure. In the illustrated example, the electrical connections between the socket 116 and the circuit board 118 are aligned with the second portion 133 of the socket 116 and spaced apart from the first portion 129 of the socket 116. The coupling components 138 electrically couple the first semiconductor package 102 via the pins 140 in the second portion 133 of the socket 116 to interconnects 142 (e.g., electrical traces or other routing) in the circuit board 118. In some examples, the socket 116 includes one or more standoffs 143 which may assist in supporting the socket 116 with the circuit board 118, ensuring proper electrical connections and preventing misalignment issues during installation. In some examples, the standoffs 143 are an integral component of the socket 116. In other examples, the standoffs 143 are distinct and separate from the socket 116. In some examples, the standoffs 143 may be omitted.

The IC device assembly 100 illustrated in FIG. 1 includes a PCIe connector 144 coupled to the first face 136 of the circuit board 118. The connector 144 is coupled to the coupling components 138 via the interconnects 142. The connector 144 couples the circuit board 118 with a cable that connects to a peripheral component interconnect express (PCIe) modules or devices.

To enable the electrical coupling of the various components of the example IC device assembly 100 of FIG. 1, consideration needs to be given to the thicknesses of the different components. For instance, the mid-level interconnects corresponding to the ball grid arrays 109, 125 between the semiconductor packages 102, 120 and the interposer 106 have a first thickness 146. Using known interconnect technology, the first thickness 146 is approximately 0.257 millimeter (mm). However, in other examples, the first thickness 146 can be more or less than this distance. Further, the interposer 106 has a second thickness 148 that is largely driven by the number of metal layers needed to implement all electrical routing between components to be interconnected. Some interposers in known PoINT devices include as many as 20 metal routing layers which results in a thickness of approximately 1.6 mm. However, in such known PoINT devices, the interposer includes routing for PCIe signals. Unlike such known PoINT devices, the interposer 106 of the example PoINT device 101 does not need any metal routing for PCIe signals because such signals bypass the interposer 106 and pass directly from the first semiconductor package 102 to the socket 116. The PCIe signals are routed through the pins 140 in the socket 116 without passing through the interposer 106, thereby reducing the number of routing layers needed in the interposer 106. Accordingly, in some examples, the interposer 106 can have significantly fewer metal layers and, thus, can have a thickness 148 significantly less than 1.6 mm. Specifically, in some examples, the thickness 148 can be less than or equal to 1.4 mm, less than or equal to 1.2 mm, less than or equal to 1.0 mm, etc. By routing PCIe signals directly through the pins 140 without going through the interposer 106, the PCIe signals have one less mid-level interconnect interface to pass through. This reduces the number of impedance discontinuities for communications with external components (e.g., PCIe connected devices) which results in less signal reflections and improves signal integrity (SI). Maintaining signal integrity in communications ensures reliable data transmission at high speed.

The combined distance of the first thickness 146 and the second thickness 148 corresponds to the approximate distance the contact surface 128 of the socket 106 needs to be spaced apart from the bottom surface 110 of the semiconductor package 102. In some examples, the distance between the bottom surface 110 of the semiconductor package 102 and the contact surface 128 of the socket 116 is slightly greater than the combined distance of the first and second thicknesses 146, 148 to ensure the mid-level interconnects (e.g., the ball grid arrays 109, 125) do not get crushed during insertion of the PoINT device 101 into the socket 106. More particularly, as shown in FIG. 1, the distance between the semiconductor package 102 and the contact surface 128 of the socket 116 corresponds to the first thickness 146, the second thickness 148, and a third thickness 150. In some examples, the third thickness 150 is relatively small (e.g., 0.3 mm or less, 0.2 mm or less, 0.15 mm or less, 0.14 mm or less, 0.1 mm or less, etc.). In some examples, the extra distance corresponding to the third thickness 150 is filled by a compressible material 130 positioned between the interposer 106 and the contact surface 128 of the socket 116. In some examples, the compressible material 130 has a thickness larger than the third thickness 150 when the compressible material 130 is uncompressed (as shown in FIG. 2) but that compresses down to the third thickness 150 when the PoINT device 101 is inserted into the socket 116 (as shown in FIG. 1).

In some examples, the compressible material 130 is attached (e.g., adhered) to the second side 126 of the interposer 106. In some examples, the compressible material 130 is attached (e.g., adhered) to the contact surface 128 of the socket 116. In some examples, the compressible material 130 can be a silicon rubber with an example hardness scale of 40A durometer. However, any other suitable material may also be used. In some examples, the first portion 129 of the socket 116 (e.g., the portion associated with the contact surface 128) can have a first thickness 152 and the second portion 133 of the socket 116 can have a second thickness 154. As shown, the first thickness 152 is less than the second thickness 154. In some examples, as shown in the illustrated example, the first and second portions 129, 133 share a common bottom surface 156 (e.g., the underside, board facing surface) of the socket 116 (e.g., the first and second portions 129, 133 are flush with one another along an underside of the socket 116). In other examples, the first and second portions 129, 133 can be offset relative to one another along the bottom surface 156 of the socket 116. In the illustrated example, the first portion 129 is positioned between the semiconductor dies and/or packages 102, 120 and the standoffs 143 on the circuit board 118 when the semiconductor die 102, 120 is coupled to the socket. In this example, the first thickness 152 corresponds to the distance between the contact surface 128 on the socket 116 and the bottom surface 156 of the socket 116. In some examples, the first thickness 152 is less than or equal to 1 mm (e.g., less than or equal to 0.75 mm, less than or equal to 0.6 mm, less than or equal to 0.5 mm, less than or equal to 0.4 mm, etc.).

In the illustrated example, the second portion 133 of the socket 116 is positioned between the semiconductor die or package 102 and the circuit board 118 when the semiconductor package 102 is coupled to the socket 116. The second portion 133 of the socket 116 includes the pins 140. The pins 140 extend through the second thickness 154 of the second portion of the socket 116. The second portion 133 of the socket 116 is not between the interposer 106 and the circuit board 118 when the interposer 106 is inserted into the socket 116. This is because the second portion 133 of the socket 116 extends through the opening or cutout 131 of the interposer 106. Hence, the first thickness 152 of the first portion 129 of the socket 116 is less than the second thickness 154 of the second portion 133 of the socket 116. More particularly, in some examples, the difference between the first thickness 152 and the second thickness 154 corresponds to the combined thickness of the thickness 146 of the balls in the ball grid arrays 109, 125, the thickness 148 of the interposer 106, and the thickness 150 of the compressible material 130 (when compressed) as described above. In this example, the second thickness 154 corresponds to the distance between the upper contact surface 114 on the socket 116 and the bottom surface 156 of the socket 116. In some examples, the second thickness 154 is less than or equal to 3 mm (e.g., less than or equal to 2.5 mm, less than or equal to 2 mm, less than or equal to 1. mm, etc.). In some examples, the socket 116 has an overall height 158 that corresponds to the combined thickness associated with the second thickness 154 of the second portion 133 and the thickness or height of the standoffs 143 that define the gap between the bottom surface 156 and the circuit board 118.

FIG. 3 illustrates an exploded view of the example IC device assembly 100 of FIG. 1. The first semiconductor package 102 is coupled to the interposer 106 that includes an opening or a cutout 131. The opening 131 extends from the first side 104 of the interposer 106 to the second side 126 of the interposer 106. The first side 104 is opposite the second side 126 of the interposer 106. The first contacts 108 on the bottom surface of the semiconductor package 102 couple to the ball grid array 109 on the interposer 106. In this example, the ball grid array 109 is adjacent to the cutout 131. More particularly, in this example, the ball grid array 109 surrounds the cutout 131. In other examples, the ball grid array 109 may adjacent some of the side of the cutout 131 but not all of them. The interposer 106 is dimensioned to be inserted into the socket 116 (e.g., adjacent the contact surface 128 associated with the first portion 129 of the socket 116). The second side 126 of the interposer 106 faces towards the socket 116. The socket 116 is mounted on top of the circuit board 118. As shown in the illustrated example, the semiconductor package 102 extends across (e.g., covers) the opening or cutout 131 when the package 102 is coupled to the interposer 106 via the ball grid array 108. The second contacts 112 of the semiconductor package 102 electrically couple to the circuit board 118 via the pins 140 in the second portion 133 of the socket 116 that is dimensioned to extend through the opening or cutout 131 to reach the underside of the semiconductor package 102 where the second contacts 112 are located (as shown in FIGS. 1 and 2). In this arrangement, the interconnects made by the electrical coupling of the second contacts 112 with the pins 140 bypass the interposer 106. The interposer 106 is spaced apart from the pins 140. More particularly, as shown in the illustrated example, the interposer 106 is dimensioned to extend around the second portion 133 of the socket 116 where the pins 140 are located. In some examples, the interposer 106 may not extend completely around the second portion 133. For instance, in some examples, the interposer 133 may be generally “C” shaped with the opening or cutout 131 extending to an edge or perimeter of the interposer 106. In other examples, the interposer 106 may include more than one discrete section that are spaced apart from one another (e.g., positioned on opposite sides of the second portion 133 of the socket 116.

In the illustrated example of FIG. 3, one or more second semiconductor packages 120 (e.g., memory package) are coupled to the interposer 106 on the first side or surface 104 of the interposer 106 (e.g., via the ball grid arrays 125 shown in FIGS. 1 and 2). In some examples, the second semiconductor package 120 are electrically coupled to the processor package 102 through the interposer 106, and independent of the socket 116. The connection between the semiconductor packages 102, 120 through the interposer 106 via the mid-level interconnect has a shorter interconnect compared to a conventional architecture which has an interconnect through the interposer 106 and the socket 116, and between the socket 116 and the circuit board 118. This shorter interconnect length improves performance of artificial intelligence (AI) and/or high performance computing (HPC) applications.

In some examples, as shown, the second portion 133 of the socket 116 includes an opening or recess 202 to provide space for components (e.g., a power deliver capacitor) attached to the underside of the semiconductor package 102.

FIG. 4 is a bottom view of the example semiconductor package 102 of the example PoINT device 101 of FIGS. 1-3. In this example, the semiconductor package 102 includes the first contacts 108 (e.g., contact pads) and the second contacts 112 on the mounting surface 110 of the semiconductor package 102. As shown in the illustrated example, ones of the first contact pads 108 have a first shape 402 that is different from a second shape 404 of the second contact pads 112. In some examples, the different shapes 402, 404 are based on the different modes of electrical coupling with the adjacent components (e.g., the interposer 106 and the socket 116. More particularly, in this example, the first contact pads 108 are ball grid array pads having a first shape 402 that is circular and the second contacts 112 having a second shape 404 that is rectangular. In other examples, the first contact pads 108 and/or the second contact pads 112 can be any other suitable shape. In some examples, the first contact pads 108 and the second contacts pads 112 have the same shape. In some such examples, the pads 108, 112 may nevertheless be different in size.

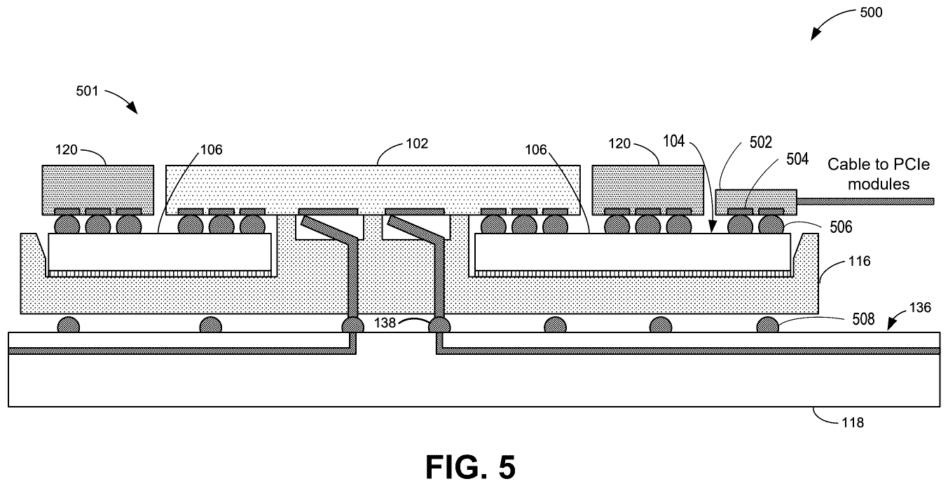

FIG. 5 is a cross-sectional view of another example IC device assembly 500 in accordance with teachings disclosed herein. The example IC device assembly 500 includes an example PoINT device 501 that is similar to the PoINT device 101 of FIGS. 1-3. Accordingly, the same reference numbers will be used for the same or similar features and the descriptions of such features provided above in connection with FIGS. 1-4 apply equally to the corresponding features shown in the illustrated example of FIG. 5. The example PoINT device 501 of FIG. 5 differs from the example PoINT device 101 of FIGS. 1-3 in that the interposer 106 is structured to provide space to support an example peripheral component connector 502 mounted thereon in addition to the second semiconductor packages 120. In this example, the peripheral component connector 502 is coupled to the first side 104 of the interposer 106 via an array of contact pads or lands 504 on the bottom surface of the peripheral component connector 502. The array of contact pads or lands 504 on the peripheral component connector 502 electrically couple to the interposer 106 via an associated ball grid array 506 on the interposer 106. In some examples, the peripheral component connector 502 is electrically coupled to one or more of the semiconductor packages 102, 120 via the interposer 106 and independent of the socket 116. In this example, the peripheral component connector 502 is a peripheral component interconnect express (PCIe) connector. However, in other examples, the peripheral component connector 502 can be any other suitable component connector.

The example IC device assembly 500 of FIG. 5 differs from the example IC device assembly 100 of FIGS. 1-3 in that the standoffs 146 adjacent the circuit board 118 are omitted. Rather, in the illustrated example of FIG. 5, the first face 136 of the circuit board 118 includes one or more dummy bumps 508. As used herein, dummy bumps are bumps that are not used to carry electrical signals. In this example, the dummy bumps 508 provide structural support to the underside of the socket 116 (hence, the reason the standoffs 143 shown in FIGS. 1 and 2 are omitted). In some examples, the dummy bumps 508 are similarly sized and shaped to the coupling components 138 (e.g., electrical contacts or interconnects) used to electrically and mechanically couple the socket 116 to the circuit board 118 and enable the electrical coupling of the semiconductor package 102 to the circuit board 118 through the socket 116 (and independent of the interposer 106). In some examples, the dummy bumps 508 are disposed on the first face 136 of the circuit board 118.

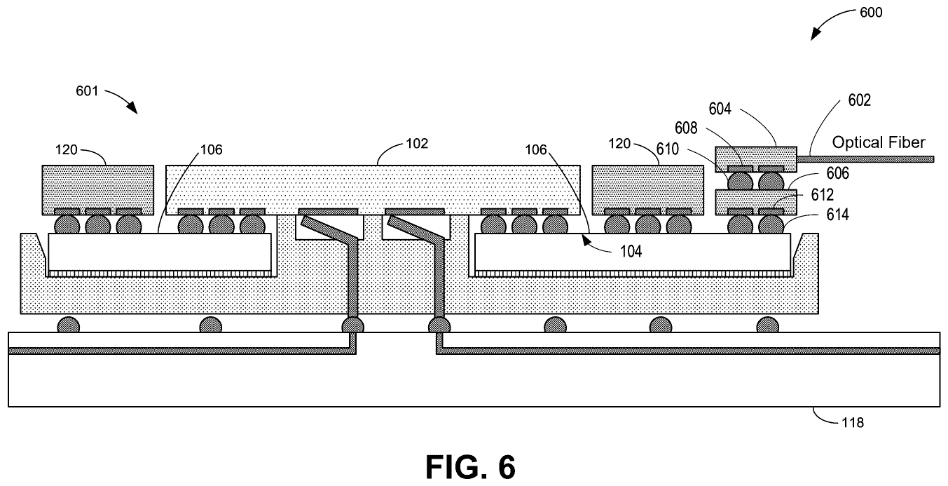

FIG. 6 is a cross-sectional view of another example IC device assembly 600 in accordance with teachings disclosed herein. The example IC device assembly 600 includes an example PoINT device 601 that is similar to the PoINT device 501 of FIG. 5 (and, by extension, similar to the PoINT device 101 of FIGS. 1-3). Accordingly, the same reference numbers will be used for the same or similar features and the descriptions of such features provided above in connection with FIGS. 1-5 apply equally to the corresponding features shown in the illustrated example of FIG. 6. The example PoINT device 601 of FIG. 5 differs from the example PoINT devices 101, 501 of FIGS. 1-5 in that the interposer 106 is structured to provide space to support an electronic integrated circuit (EIC) 606 that is electrically coupled with a photonic integrated circuit (PIC) 604. More particularly, in this example, the PIC 604 is stacked on top of the EIC 606. In some examples, an optical fiber cable 602 is coupled to the photonic integrated circuit (PIC) 604 to enable optical communication with an external component. In this example, the PIC 604 includes contact pads 608. In some examples, the PIC 604 may include balls, pins, and/or pads, in addition to or instead of the contact pads 608, to enable the electrical coupling of the PIC 604 to the EIC 606. The array of contact pads 608 (e.g., ball grid array pads) electrically couples to the EIC 606 via a ball grid array 610. The EIC 606 includes contact pads 612. In some examples, the EIC 606 may include balls, pins, and/or pads, in addition to or instead of the contact pads 612, to enable the electrical coupling of the EIC 606 to the interposer 106. The array of contact pads 612 (e.g., ball grid array pads) electrically couples to the first side 104 of the interposer 106 via a ball grid array 614.

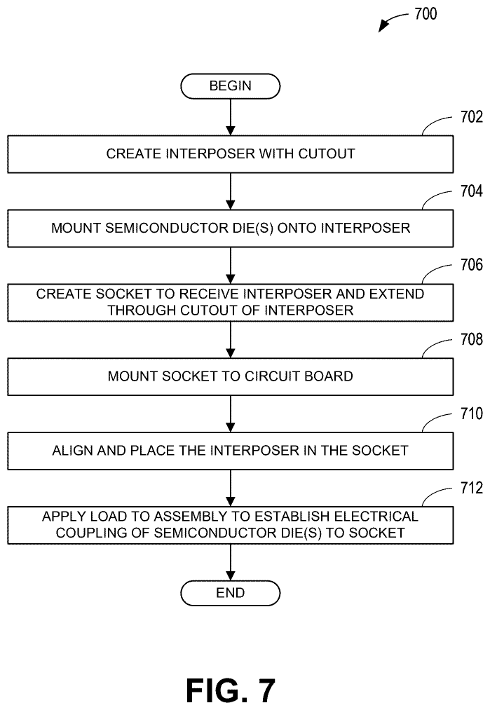

FIG. 7 is a flowchart representative of an example method to manufacture any one of the example IC device assemblies 100, 500, 600 of FIGS. 1-6. The operations 700 begin at block 702, at which the interposer 106 (FIG. 1) with the cutout 131 (FIG. 1) is created. At block 704, semiconductor die(s) 102, 120 (FIG. 1) are mounted onto the interposer 106. At block 706, the socket 116 (FIG. 1) is created to receive the interposer 106 and extend through the cutout 131 of the interposer 106. In some examples, block 706 can be implemented independent of (e.g., parallel with and/or before) blocks 702 and 704. At block 708, the socket 116 is mounted on the circuit board 118. In some examples, block 708 can also be implemented independent of (e.g., parallel with and/or before) blocks 702 and 704. At block 710, the interposer 106 is aligned and placed in the socket 116. At block 712, a load is applied to the IC device assemblies of FIGS. 1-6 to establish electrical coupling of the semiconductor die(s) 102, 120 to the socket 116. In some examples, a load is applied because the interposer 106 is compression-mounted interconnect devices that are positioned between the socket 116 or circuit board 118 to allow an electrical signal to pass through.

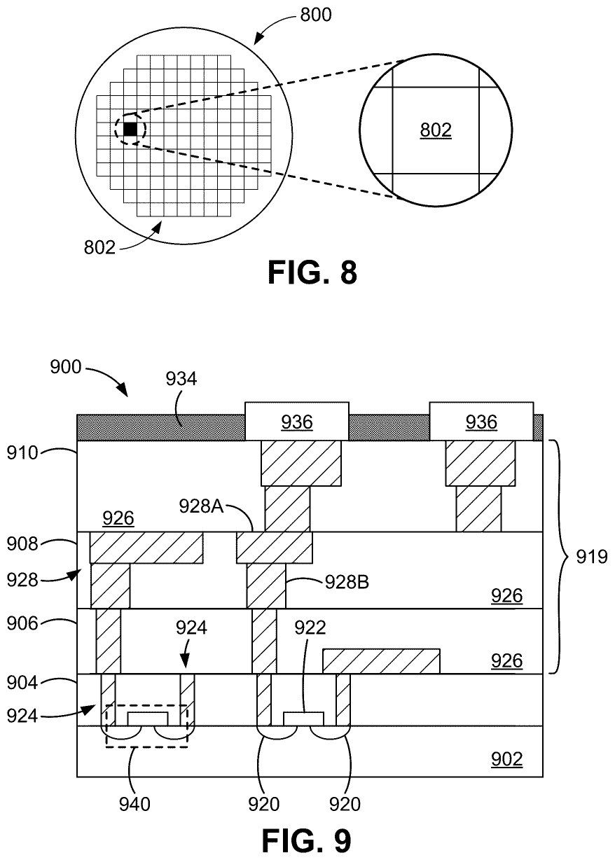

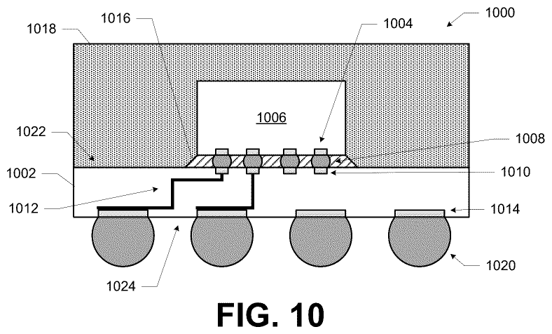

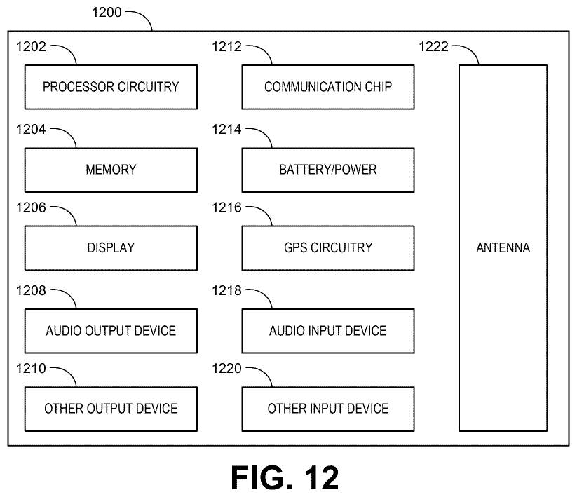

FIG. 8 is a top view of a wafer 800 and dies 802 that may be included in an IC package (e.g., as discussed below with reference to FIG. 10) in accordance with any of the examples disclosed herein (e.g., the dies 802 may correspond to any one of the example semiconductor packages 102, 120 of FIGS. 1-8, the connector 502 of FIG. 5, the PIC 604 of FIG. 6, and/or the EIC 606 of FIG. 6). The wafer 800 includes semiconductor material and one or more dies 802 having circuitry. Each of the dies 802 may be a repeating unit of a semiconductor product. After the fabrication of the semiconductor product is complete, the wafer 800 may undergo a singulation process in which the dies 802 are separated from one another to provide discrete “chips.” The die 802 includes one or more transistors (e.g., some of the transistors 940 of FIG. 9, discussed below), supporting circuitry to route electrical signals to the transistors, passive components (e.g., traces, resistors, capacitors, inductors, and/or other circuitry), and/or any other components. In some examples, the die 802 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. Multiple ones of these devices may be combined on a single die 802. For example, a memory array of multiple memory circuits may be formed on a same die 802 as programmable circuitry (e.g., the processor circuitry 1202 of FIG. 12) and/or other logic circuitry. Such memory may store information for use by the programmable circuitry.

FIG. 9 is a cross-sectional side view of an IC device 900 that may be included in an IC package (e.g., as discussed below with reference to FIG. 10), in accordance with any of the examples disclosed herein (e.g., the device 900 may correspond to any one of the example semiconductor packages 102, 120 of FIGS. 1-8, the connector 502 of FIG. 5, the PIC 604 of FIG. 6, and/or the EIC 606 of FIG. 6). One or more of the IC devices 900 may be included in one or more dies 802 (FIG. 8). The IC device 900 may be formed on a die substrate 902 (e.g., the wafer 800 of FIG. 8) and may be included in a die (e.g., the die 802 of FIG. 8). The die substrate 902 may be a semiconductor substrate including semiconductor materials including, for example, n-type or p-type materials systems (or a combination of both). The die substrate 902 may include, for example, a crystalline substrate formed using a bulk silicon or a silicon-on-insulator (SOI) substructure. In some examples, the die substrate 902 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an IC device 900 may be used. The die substrate 902 may be part of a singulated die (e.g., the dies 802 of FIG. 8) or a wafer (e.g., the wafer 800 of FIG. 8).

The IC device 900 may include one or more device layers 904 disposed on and/or above the die substrate 902. The device layer 904 may include features of one or more transistors 940 (e.g., metal oxide semiconductor field-effect transistors (MOSFETs)) formed on the die substrate 902. The device layer 904 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 940 may include a gate 922 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 940 along the source-channel-drain direction, the gate electrode may include a U-shaped structure that includes a bottom portion substantially parallel to the surface of the die substrate 902 and two sidewall portions that are substantially perpendicular to the top surface of the die substrate 902. In other examples, at least one of the metal layers that form the gate electrode may be a planar layer that is substantially parallel to the top surface of the die substrate 902 and does not include sidewall portions substantially perpendicular to the top surface of the die substrate 902. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of corresponding transistor(s) 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 920 may be formed using one or more alternate semiconductor materials such as germanium or a group III-V material or alloy. In further examples, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the IC device 900.

The interconnect structures 928 may be arranged within the interconnect layers 906-910 to route electrical signals according to a wide variety of designs (in particular, the arrangement is not limited to the particular configuration of interconnect structures 928 depicted in FIG. 9). Although a particular number of interconnect layers 906-910 is depicted in FIG. 9, examples of the present disclosure include IC devices having more or fewer interconnect layers than depicted.

In some examples, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and/or out of the page from the perspective of FIG. 9. The vias 928b may be arranged to route electrical signals in a direction of a plane that is substantially perpendicular to the surface of the die substrate 902 upon which the device layer 904 is formed. In some examples, the vias 928b may electrically couple lines 928a of different interconnect layers 906-910 together.

The interconnect layers 906-910 may include a dielectric material 926 disposed between the interconnect structures 928, as shown in FIG. 9. In some examples, the dielectric material 926 disposed between the interconnect structures 928 in different ones of the interconnect layers 906-910 may have different compositions; in other examples, the composition of the dielectric material 926 between different interconnect layers 906-910 may be the same.

A first interconnect layer 906 (referred to as Metal 1 or “M1”) may be formed directly on the device layer 904. In some examples, the first interconnect layer 906 may include lines 928a and/or vias 928b, as shown. The lines 928a of the first interconnect layer 906 may be coupled with contacts (e.g., the S/D contacts 924) of the device layer 904.

A second interconnect layer 908 (referred to as Metal 2 or “M2”) may be formed directly on the first interconnect layer 906. In some examples, the second interconnect layer 908 may include vias 928b to couple the lines 928a of the second interconnect layer 908 with the lines 928a of the first interconnect layer 906. Although the lines 928a and the vias 928b are structurally delineated with a line within each interconnect layer (e.g., within the second interconnect layer 908) for the sake of clarity, the lines 928a and the vias 928b may be structurally and/or materially contiguous (e.g., simultaneously filled during a dual-damascene process) in some examples.

A third interconnect layer 910 (referred to as Metal 3 or “M3”) (and additional interconnect layers, as desired) may be formed in succession on the second interconnect layer 908 according to similar techniques and/or configurations described in connection with the second interconnect layer 908 or the first interconnect layer 906. In some examples, the interconnect layers that are “higher up” in the metallization stack 919 in the IC device 900 (i.e., further away from the device layer 904) may be thicker.

The IC device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to other external devices. For example, solder bonds may be formed on the one or more conductive contacts 936 to mechanically and/or electrically couple a chip including the IC device 900 with another component (e.g., a circuit board). The IC device 900 may include additional or alternate structures to route the electrical signals from the interconnect layers 906-910; for example, the conductive contacts 936 may include other analogous features (e.g., posts) that route the electrical signals to external components.

FIG. 10 is a cross-sectional view of an example IC package 1000 constructed in accordance with teachings disclosed herein. In some examples, the IC package 1000 may correspond to any one of the example semiconductor packages 102, 120 of FIGS. 1-8, the connector 502 of FIG. 5, the PIC 604 of FIG. 6, and/or the EIC 606 of FIG. 6. The package substrate 1002 may include a dielectric material and may have conductive pathways extending through the dielectric material between upper and lower faces 1022, 1024, and/or between different locations on the upper face 1022, and/or between different locations on the lower face 1024. These conductive pathways may take the form of any of the interconnects 928 discussed above with reference to FIG. 9.

The IC package 1000 may include a die 1006 coupled to the package substrate 1002 via conductive contacts 1004 of the die 1006, first-level interconnects 1008, and conductive contacts 1010 of the package substrate 1002. The conductive contacts 1010 may be coupled to conductive pathways 1012 through the package substrate 1002, allowing circuitry within the die 1006 to electrically couple to various ones of the conductive contacts 1014. The first-level interconnects 1008 illustrated in FIG. 10 are solder bumps, but any suitable first-level interconnects 1008 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

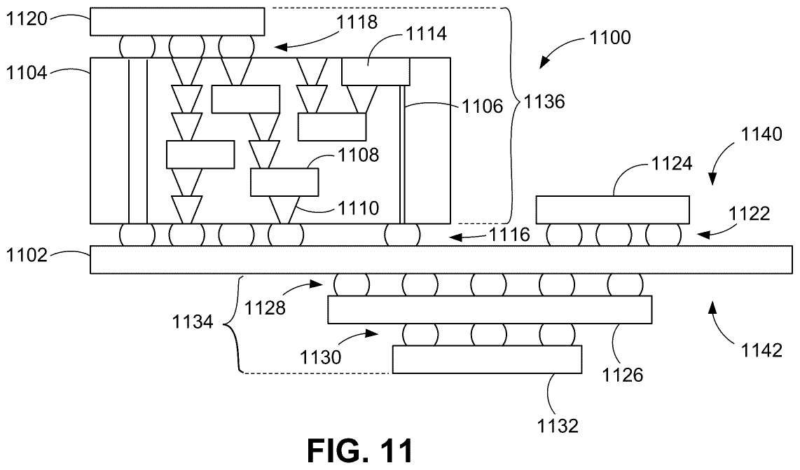

In some examples, an underfill material 1016 may be disposed between the die 1006 and the package substrate 1002 around the first-level interconnects 1008, and/or a mold compound 1018 may be disposed around the die 1006 and in contact with the package substrate 1002. In some examples, the underfill material 1016 may be the same as the mold compound 1018. Example materials that may be used for the underfill material 1016 and the mold compound 1018 are epoxy mold materials, as suitable. Second-level interconnects 1020 may be coupled to the conductive contacts 1014. The second-level interconnects 1020 illustrated in FIG. 10 are solder balls (e.g., for a ball grid array arrangement), but any suitable second-level interconnects 1020 may be used (e.g., pins in a pin grid array arrangement or lands in a land grid array arrangement). The second-level interconnects 1020 may be used to couple the IC package 1000 to another component, such as a circuit board (e.g., a motherboard), an interposer, or another IC package, as known in the art and as discussed below with reference to FIG. 11.

In FIG. 10, the IC package 1000 is a flip chip package, and includes a package substrate 1002. The number and location of the package substrate 1002 of the IC package 1000 is simply illustrative. The die 1006 may take the form of any of the examples of the die 1202 discussed herein (e.g., may include any of the examples of the IC device 900).

Although the IC package 1000 illustrated in FIG. 10 is a flip chip package, other package architectures may be used. For example, the IC package 1000 may be a ball grid array (BGA) package, such as an embedded wafer-level ball grid array (eWLB) package. In another example, the IC package 1000 may be a wafer-level chip scale package (WLCSP) or a panel fanout (FO) package. Although a single die 1006 is illustrated in the IC package 1000 of FIG. 10, an IC package 1000 may include multiple dies 1006 (e.g., with one or more of the multiple dies 1006 coupled to the package substrate 1002). An IC package 1000 may include additional passive components, such as surface-mount resistors, capacitors, and/or inductors disposed on the first face 1022 or the second face 1024 of the package substrate 1002. More generally, an IC package 1000 may include any other active and/or passive components known in the art.

FIG. 11 is a cross-sectional side view of an IC device assembly 1100 disclosed herein. In some examples, the IC device assembly 1100 includes and/or corresponds to any one of the example IC device assemblies 100, 500, 600 of FIGS. 1-6, and/or any one of the associated examples PoINT devices 101, 501, 601 of FIGS. 1-6. The IC device assembly 1100 includes a number of components disposed on a circuit board 1102 (which may be, for example, a motherboard). The IC device assembly 1100 includes components disposed on a first face 1140 of the circuit board 1102 and an opposing second face 1142 of the circuit board 1102; generally, components may be disposed on one or both faces 1140 and 1142.

In some examples, the circuit board 1102 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 1102. In other examples, the circuit board 1102 may be a non-PCB substrate.

The IC device assembly 1100 illustrated in FIG. 11 includes a package-on-interposer structure 1136 coupled to the first face 1140 of the circuit board 1102 by coupling components 1116. The coupling components 1116 may electrically and mechanically couple the package-on-interposer structure 1136 to the circuit board 1102, and may include solder balls (as shown in FIG. 11), male and female portions of a socket, an adhesive, an underfill material, and/or any other suitable electrical and/or mechanical coupling structure.

The package-on-interposer structure 1136 may include an IC package 1120 coupled to an interposer 1104 by coupling components 1118. The coupling components 1118 may take any suitable form for the application, such as the forms discussed above with reference to the coupling components 1116. Although a single IC package 1120 is shown in FIG. 11, multiple IC packages may be coupled to the interposer 1104; indeed, additional interposers may be coupled to the interposer 1104. The interposer 1104 may provide an intervening substrate used to bridge the circuit board 1102 and the IC package 1120. The IC package 1120 may be or include, for example, a die (the die 802 of FIG. 8), an IC device (e.g., the IC device 900 of FIG. 9), or any other suitable component. Generally, the interposer 1104 may spread a connection to a wider pitch or reroute a connection to a different connection. For example, the interposer 1104 may couple the IC package 1120 (e.g., a die) to a set of BGA conductive contacts of the coupling components 1116 for coupling to the circuit board 1102. In the example illustrated in FIG. 11, the IC package 1120 and the circuit board 1102 are attached to opposing sides of the interposer 1104; in other examples, the IC package 1120 and the circuit board 1102 may be attached to a same side of the interposer 1104. In some examples, three or more components may be interconnected by way of the interposer 1104.

In some examples, the interposer 1104 may be formed as a PCB, including multiple metal layers separated from one another by layers of dielectric material and interconnected by electrically conductive vias. In some examples, the interposer 1104 may be formed of an epoxy resin, a fiberglass-reinforced epoxy resin, an epoxy resin with inorganic fillers, a ceramic material, or a polymer material such as polyimide. In some examples, the interposer 1104 may be formed of alternate rigid or flexible materials that may include the same materials described above for use in a semiconductor substrate, such as silicon, germanium, and other group III-V and group IV materials. The interposer 1104 may include metal interconnects 1108 and vias 1110, including but not limited to through-silicon vias (TSVs) 1106. The interposer 1104 may further include embedded devices 1114, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 1104. The package-on-interposer structure 1136 may take the form of any of the package-on-interposer structures known in the art.

The IC device assembly 1100 may include an IC package 1124 coupled to the first face 1140 of the circuit board 1102 by coupling components 1122. The coupling components 1122 may take the form of any of the examples discussed above with reference to the coupling components 1116, and the IC package 1124 may take the form of any of the examples discussed above with reference to the IC package 1120.

The IC device assembly 1100 illustrated in FIG. 11 includes a package-on-package structure 1134 coupled to the second face 1142 of the circuit board 1102 by coupling components 1128. The package-on-package structure 1134 may include a first IC package 1126 and a second IC package 1132 coupled together by coupling components 1130 such that the first IC package 1126 is disposed between the circuit board 1102 and the second IC package 1132. The coupling components 1128, 1130 may take the form of any of the examples of the coupling components 1116 discussed above, and the IC packages 1126, 1132 may take the form of any of the examples of the IC package 1120 discussed above. The package-on-package structure 1134 may be configured in accordance with any of the package-on-package structures known in the art.

FIG. 12 is a block diagram of an example electrical device 1200. For example, any suitable ones of the components of the electrical device 1200 may include one or more of the device assemblies 1100, IC devices 900, or dies 802 disclosed herein. A number of components are illustrated in FIG. 12 as included in the electrical device 1200, but any one or more of these components may be omitted or duplicated, as suitable for the application. In some examples, some or all of the components included in the electrical device 1200 may be attached to one or more motherboards. In some examples, some or all of these components are fabricated onto a single system-on-a-chip (SoC) die.

Additionally, in various examples, the electrical device 1200 may not include one or more of the components illustrated in FIG. 12, but the electrical device 1200 may include interface circuitry for coupling to the one or more components. For example, the electrical device 1200 may not include a display 1206, but may include display interface circuitry (e.g., a connector and driver circuitry) to which a display 1206 may be coupled. In another set of examples, the electrical device 1200 may not include an audio input device 1218 (e.g., microphone) or an audio output device 1208 (e.g., a speaker, a headset, earbuds, etc.), but may include audio input or output device interface circuitry (e.g., connectors and supporting circuitry) to which an audio input device 1218 or audio output device 1208 may be coupled.

The electrical device 1200 may include programmable circuitry 1202 (e.g., one or more processing devices). The programmable circuitry 1202 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 1200 may include a memory 1204, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 1204 may include memory that shares a die with the programmable circuitry 1202. This memory may be used as cache memory and may include embedded dynamic random access memory (eDRAM) or spin transfer torque magnetic random access memory (STT-MRAM).

In some examples, the electrical device 1200 may include a communication chip 1212 (e.g., one or more communication chips). For example, the communication chip 1212 may be configured for managing wireless communications for the transfer of data to and from the electrical device 1200. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 1212 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1212 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 1212 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 1212 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1212 may operate in accordance with other wireless protocols in other examples. The electrical device 1200 may include an antenna 1222 to facilitate wireless communications and/or to receive other wireless communications (such as AM or FM radio transmissions).

In some examples, the communication chip 1212 may manage wired communications, such as electrical, optical, or any other suitable communication protocols (e.g., the Ethernet). As noted above, the communication chip 1212 may include multiple communication chips. For instance, a first communication chip 1212 may be dedicated to shorter-range wireless communications such as Wi-Fi or Bluetooth, and a second communication chip 1212 may be dedicated to longer-range wireless communications such as global positioning system (GPS), EDGE, GPRS, CDMA, WiMAX, LTE, EV-DO, or others. In some examples, a first communication chip 1212 may be dedicated to wireless communications, and a second communication chip 1212 may be dedicated to wired communications.

The electrical device 1200 may include battery/power circuitry 1214. The battery/power circuitry 1214 may include one or more energy storage devices (e.g., batteries or capacitors) and/or circuitry for coupling components of the electrical device 1200 to an energy source separate from the electrical device 1200 (e.g., AC line power).

The electrical device 1200 may include a display 1206 (or corresponding interface circuitry, as discussed above). The display 1206 may include any visual indicators, such as a heads-up display, a computer monitor, a projector, a touchscreen display, a liquid crystal display (LCD), a light-emitting diode display, or a flat panel display.

The electrical device 1200 may include an audio output device 1208 (or corresponding interface circuitry, as discussed above). The audio output device 1208 may include any device that generates an audible indicator, such as speakers, headsets, or earbuds.

The electrical device 1200 may include an audio input device 1218 (or corresponding interface circuitry, as discussed above). The audio input device 1218 may include any device that generates a signal representative of a sound, such as microphones, microphone arrays, or digital instruments (e.g., instruments having a musical instrument digital interface (MIDI) output).

The electrical device 1200 may include GPS circuitry 1216. The GPS circuitry 1216 may be in communication with a satellite-based system and may receive a location of the electrical device 1200, as known in the art.

The electrical device 1200 may include any other output device 1210 (or corresponding interface circuitry, as discussed above). Examples of the other output device 1210 may include an audio codec, a video codec, a printer, a wired or wireless transmitter for providing information to other devices, or an additional storage device.

The electrical device 1200 may include any other input device 1220 (or corresponding interface circuitry, as discussed above). Examples of the other input device 1220 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1200 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 1200 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein “substantially real time” refers to occurrence in a near instantaneous manner recognizing there may be real world delays for computing time, transmission, etc. Thus, unless otherwise specified, “substantially real time” refers to real time +1second.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that connect a semiconductor package to a circuit board. More particularly, examples disclosed herein resolve challenges of more impedance discontinuities and signal reflections arising from circuit assemblies using PoINT devices having an additional interconnect transition between the dies and/or packages and the interposer. In some examples PoINT devices disclosed herein a first package (e.g., a processor package) is to communicate directly with other components mounted onto the interposer without discontinuities defined by the transitions between the interposer and the socket, and between the socket and the circuit board. Furthermore, in some examples, the first package of some example PoINT devices disclosed herein include interconnects that bypass the interposer to directly connect with an underlying socket on a circuit board to communicate with other components via the circuit board, thereby reducing the number of mid-level interconnect interfaces between the semiconductor packages to the circuit board (e.g., without the mid-level interconnect interface between the package and an interposer).

Further examples and combinations thereof include the following:

Example 1 includes an apparatus comprising an interposer having a first side and a second side opposite the first side, and a semiconductor package coupled to the first side of the interposer via first contacts on a first surface of the semiconductor package, the semiconductor package including second contacts on the first surface of the semiconductor package, the second contacts spaced apart from the first contacts, the second contacts to electrical couple to third contacts in a socket dimensioned to receive the interposer and the semiconductor package.

Example 2 includes the apparatus of example 1, wherein the semiconductor package is a first semiconductor package, the apparatus further including a second semiconductor package coupled to the first side of the interposer via fourth contacts on the second semiconductor package.

Example 3 includes the apparatus of example 2, wherein the first semiconductor package is electrically coupled to the second semiconductor package via the interposer and independent of the socket, the first semiconductor package to be electrically coupled to an external component via the socket and independent of the interposer.

Example 4 includes the apparatus of any one of examples 2 or 3, wherein the first semiconductor package is a processor package and the second semiconductor package is a memory package.

Example 5 includes the apparatus of any one of examples 2-4, wherein the interposer is to be between the fourth contacts of the second semiconductor package and the socket, the interposer is to be between the first contacts of the first semiconductor package and the socket, and the interposer is not to be between the second contacts of the first semiconductor package and the socket.

Example 6 includes the apparatus of any one of examples 1-5, wherein the first contacts on the semiconductor package have a first shape and the second contacts on the semiconductor package have a second shape, the second shape different from the first shape.

Example 7 includes the apparatus of any one of examples 1-6, wherein the first contacts on the semiconductor package include BGA pads and the second contacts on the semiconductor package include LGA pads.

Example 8 includes the apparatus of any one of examples 1-7, wherein the interposer includes a cutout aligned with the second contacts of the semiconductor package so that the interposer is spaced apart from the second contacts.

Example 9 includes the apparatus of example 8, wherein the socket is to extend into the cutout towards the semiconductor package.

Example 10 includes the apparatus of any one of examples 1-9, further including a compressible material to be between the interposer and the socket.

Example 11 includes the apparatus of example 10, wherein the compressible material is attached to the second side of the interposer.

Example 12 includes an apparatus comprising an interposer to fit into a socket, a first surface of the interposer to face towards the socket, the interposer including an opening extending from the first surface to a second surface of the interposer, the second surface opposite the first surface, and a semiconductor package coupled to the second surface of the interposer, the semiconductor package to extend across the opening of the interposer, the semiconductor package including contacts exposed through the opening in the interposer, the contacts to electrically couple to a portion of the socket that is to extend through the opening in the interposer.

Example 13 includes the apparatus of example 12, wherein the interposer is devoid of electrical connections with the socket along the second surface of the interposer.

Example 14 includes the apparatus of any one of examples 12 or 13, further including a peripheral component connector coupled to the second surface of the interposer, the peripheral component connector electrically coupled to the semiconductor package via the interposer and independent of the socket, the peripheral component connector including at least one of a peripheral component interconnect express (PCIe) connector or a photonic integrated circuit (PIC).

Example 15 includes an apparatus comprising a socket to be mounted on a circuit board, a substrate to be inserted into the socket, the substrate including a core, the core including woven glass fibers embedded in an epoxy resin, and a semiconductor die to be electrically coupled to the substrate via first contacts and to be electrically coupled to the circuit board via pins in the socket, the substrate to be spaced apart from the pins.

Example 16 includes the apparatus of example 15, wherein the semiconductor die is a first semiconductor die, the apparatus further including a second semiconductor die, the second semiconductor die electrically coupled to the first semiconductor die through the substrate and independent of the socket.

Example 17 includes the apparatus of any one of examples 15 or 16, wherein the socket includes a first portion having a first thickness and a second portion having a second thickness, the first thickness less than the second thickness, the first portion positioned between the semiconductor die and the circuit board when the semiconductor die is coupled to the socket, less than all of the second portion positioned between the semiconductor die and the circuit board when the semiconductor die is coupled to the socket.

Example 18 includes the apparatus of example 17, wherein the first portion is between the substrate and the circuit board when the substrate is inserted into the socket, and no part of the second portion is between the substrate and the circuit board when the substrate is inserted into the socket.

Example 19 includes the apparatus of any one of examples 17 or 18, wherein the second portion of the socket includes the pins, the pins to extend through the second thickness of the second portion.

Example 20 includes the apparatus of any one of examples 17-19, wherein electrical connections between the socket and the circuit board are aligned with the second portion of the socket and spaced apart from the first portion of the socket.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. An apparatus comprising:
an interposer having a first side and a second side opposite the first side; and
a semiconductor package coupled to the first side of the interposer via first contacts on a first surface of the semiconductor package, the semiconductor package including second contacts on the first surface of the semiconductor package, the second contacts spaced apart from the first contacts, the second contacts to electrical couple to third contacts in a socket dimensioned to receive the interposer and the semiconductor package.

2. The apparatus of claim 1, wherein the semiconductor package is a first semiconductor package, the apparatus further including a second semiconductor package coupled to the first side of the interposer via fourth contacts on the second semiconductor package.

3. The apparatus of claim 2, wherein the first semiconductor package is electrically coupled to the second semiconductor package via the interposer and independent of the socket, the first semiconductor package to be electrically coupled to an external component via the socket and independent of the interposer.

4. The apparatus of claim 2, wherein the first semiconductor package is a processor package and the second semiconductor package is a memory package.

5. The apparatus of claim 2, wherein the interposer is to be between the fourth contacts of the second semiconductor package and the socket, the interposer is to be between the first contacts of the first semiconductor package and the socket, and the interposer is not to be between the second contacts of the first semiconductor package and the socket.

6. The apparatus of claim 1, wherein the first contacts on the semiconductor package have a first shape and the second contacts on the semiconductor package have a second shape, the second shape different from the first shape.

7. The apparatus of claim 1, wherein the first contacts on the semiconductor package include BGA pads and the second contacts on the semiconductor package include LGA pads.

8. The apparatus of claim 1, wherein the interposer includes a cutout aligned with the second contacts of the semiconductor package so that the interposer is spaced apart from the second contacts.

9. The apparatus of claim 8, wherein the socket is to extend into the cutout towards the semiconductor package.

10. The apparatus of claim 1, further including a compressible material to be between the interposer and the socket.

11. The apparatus of claim 10, wherein the compressible material is attached to the second side of the interposer.

12. An apparatus comprising:
an interposer to fit into a socket, a first surface of the interposer to face towards the socket, the interposer including an opening extending from the first surface to a second surface of the interposer, the second surface opposite the first surface; and
a semiconductor package coupled to the second surface of the interposer, the semiconductor package to extend across the opening of the interposer, the semiconductor package including contacts exposed through the opening in the interposer, the contacts to electrically couple to a portion of the socket that is to extend through the opening in the interposer.

13. The apparatus of claim 12, wherein the interposer is devoid of electrical connections with the socket along the second surface of the interposer.

14. The apparatus of claim 12, further including a peripheral component connector coupled to the second surface of the interposer, the peripheral component connector electrically coupled to the semiconductor package via the interposer and independent of the socket, the peripheral component connector including at least one of a peripheral component interconnect express (PCIe) connector or a photonic integrated circuit (PIC).

15. An apparatus comprising:
a socket to be mounted on a circuit board;
a substrate to be inserted into the socket, the substrate including a core, the core including woven glass fibers embedded in an epoxy resin; and
a semiconductor die to be electrically coupled to the substrate via first contacts and to be electrically coupled to the circuit board via pins in the socket, the substrate to be spaced apart from the pins.

16. The apparatus of claim 15, wherein the semiconductor die is a first semiconductor die, the apparatus further including a second semiconductor die, the second semiconductor die electrically coupled to the first semiconductor die through the substrate and independent of the socket.

17. The apparatus of claim 15, wherein the socket includes a first portion having a first thickness and a second portion having a second thickness, the first thickness less than the second thickness, the first portion positioned between the semiconductor die and the circuit board when the semiconductor die is coupled to the socket, less than all of the second portion positioned between the semiconductor die and the circuit board when the semiconductor die is coupled to the socket.

18. The apparatus of claim 17, wherein the first portion is between the substrate and the circuit board when the substrate is inserted into the socket, and no part of the second portion is between the substrate and the circuit board when the substrate is inserted into the socket.

19. The apparatus of claim 17, wherein the second portion of the socket includes the pins, the pins to extend through the second thickness of the second portion.

20. The apparatus of claim 17, wherein electrical connections between the socket and the circuit board are aligned with the second portion of the socket and spaced apart from the first portion of the socket.
